(19) United States
(12) Patent Application Publication
(10) Pub. No.: US 2025/0022934 A1
(43) Pub. Date: Jan. 16, 2025

(54) TRANSISTORS WITH IMPROVED THERMAL STABILITY

(71) Applicant: Taiwan Semiconductor Manufacturing Company LTD, Hsinchu (TW)

(72) Inventors: Kuo-Chang Chiang, Hsinchu (TW); Katherine H. cHIANG, New Taipei (TW); Yen-Chung Ho, Hsinchu (TW); Ming-Yen Chuang, Hsinchu (TW); Chung-Te Lin, Tainan (TW)

(21) Appl. No.: 18/221,985

(22) Filed: Jul. 14, 2023

(51) Int. Cl. H01L 29/49; H01L 21/02; H01L 21/8234; H01L 29/66; H01L 29/786

(52) U.S. Cl. CPC H01L 29/4941; H01L 21/0262; H01L 21/823431; H01L 29/6675; H01L 29/66795; H01L 29/78618; H01L 29/7869; H01L 29/78696

(57) ABSTRACT

Thermal stability of a transistor is improved in different ways. An interfacial layer between a source/drain electrode and a semiconductor layer is formed from a material having a higher bond dissociation energy than indium oxide. Alternatively, the interfacial layer is formed from a metal-doped oxide semiconductor material. As another option, a metal layer or a metal oxide layer is formed between the source/drain electrode and the interfacial layer.

### BACKGROUND

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a first method for making a transistor, in accordance with some embodiments. In this method, the metal layer or metal oxide layer is deposited after depositing the interfacial layer.

FIG. 2 is a cross-sectional view of a wafer substrate prior to forming the transistor as described in FIG. 1.

FIG. 3 is a cross-sectional view of a process step for forming the transistor.

FIG. 4 is a cross-sectional view of a process step for forming the transistor.

FIG. 5 is a cross-sectional view of a process step for forming the transistor.

FIG. 6 is a cross-sectional view of a process step for forming the transistor.

FIG. 7 is a cross-sectional view of a process step for forming the transistor.

FIG. 8 is a cross-sectional view of a process step for forming the transistor.

FIG. 9 is a cross-sectional view of a process step for forming the transistor.

FIG. 10 is a cross-sectional view of a process step for forming the transistor.

FIG. 11 is a cross-sectional view showing the final transistor, which is a bottom-gate transistor.

FIG. 12 is a flow chart illustrating a second method for making a transistor, in accordance with some embodiments. In this method, an LDD region is formed. In addition, the metal layer or metal oxide layer is deposited prior to depositing the interfacial layer.

FIG. 13 is a cross-sectional view of a process step for forming the transistor.

FIG. 14 is a cross-sectional view showing the final transistor.

FIG. 15 is a flow chart illustrating a third method for making a transistor, in accordance with some embodiments. In this method, the metal layer or metal oxide layer is deposited between two interfacial layers.

FIG. 16 is a cross-sectional view of a process step for forming the transistor.

FIG. 17 is a cross-sectional view showing the final transistor.

FIG. 18 is a cross-sectional view of a transistor having a metal doped-interfacial layer.

FIG. 19 is a flow chart illustrating a fourth method for making a transistor, in accordance with some embodiments. In this method, a top-gate transistor is formed.

FIG. 20 is a cross-sectional view of a wafer substrate prior to forming the transistor as described in FIG. 19.

FIG. 21 is a cross-sectional view of a process step for forming the transistor.

FIG. 22 is a cross-sectional view of a process step for forming the transistor.

FIG. 23 is a cross-sectional view of a process step for forming the transistor.

FIG. 24 is a cross-sectional view of a process step for forming the transistor.

FIG. 25 is a cross-sectional view of a process step for forming the transistor.

FIG. 26 is a cross-sectional view of a process step for forming the transistor.

FIG. 27 is a cross-sectional view showing a first embodiment of the final transistor.

FIG. 28 is a cross-sectional view showing a second embodiment of the final transistor.

FIG. 29 is a cross-sectional view showing a third embodiment of the final transistor.

FIG. 30 is a flow chart illustrating a fifth method for making a transistor, in accordance with some embodiments. In this method, a top-gate transistor is formed.

FIG. 31 is a cross-sectional view of a process step in a first variation of the process for forming the transistor.

FIG. 32 is a cross-sectional view of a process step in a first variation of the process for forming the transistor.

FIG. 33 is a cross-sectional view of a process step in a second variation of the process for forming the transistor.

FIG. 34 is a cross-sectional view of a process step in a second variation of the process for forming the transistor.

FIG. 35 is a cross-sectional view of a process step in a second variation of the process for forming the transistor.

FIG. 36 is a cross-sectional view showing a first embodiment of the final transistor.

FIG. 37 is a cross-sectional view showing a second embodiment of the final transistor.

FIG. 38 is a cross-sectional view showing a third embodiment of the final transistor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named components/steps and permit the presence of other components/steps. However, such description should be construed as also describing compositions or processes as “consisting of” and “consisting essentially of” the enumerated components/steps, which allows the presence of only the named components/steps and excludes other components/steps.

The present disclosure relates to transistors and other structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the transistor can be considered to be “on” the substrate, even though they do not all directly contact the substrate. The term “directly” may be used to indicate two layers directly contact each other without any layers in between them.

The present disclosure relates to methods for producing transistors having improved thermal stability. In this regard, oxide semiconductor (OS) materials have high charge mobility, which permits high speed driving and a low off current (l_{off}) for low power consumption. Thus, OS materials are often used as the semiconductor channel material in a metal-oxide-semiconductor field effect transistor (MOSFET) device.

Vₜ is the gate threshold voltage, and Iₒₙ is the on-current, which is the maximum current at a constant drain voltage. These two properties are generally inversely related to each other. The tradeoff between Vₜ and Iₒₙ can be optimized to improve device performance, but these two properties are easily impacted by stress instability. One approach to enhance the Iₒₙ while maintaining Vₜ keeping is through the use of a high-conductivity OS material having a high atomic percentage (at %) of indium (In), or by hydrogen doping.

However, ultraviolet light exposure during the photolithography process has the potential to cause high power damage, which may contribute to photogenerated holes and creation/ionization of oxygen vacancy states (Vo) in in the body of the OS material and its surface. Exposure to energy of as little as 0.001 to 1 joule may cause heating issues at small pattern sizes. In addition, photoionization generates free electrons and the transition from a neutral to an ionized Vo is accompanied by lattice relaxation, which raises the energy of the ionized Vo. This may promote “defect generation” from atomic exchange with weakly bonded hydrogen, inducing high delta-Vₜ instability during operation, threshold-voltage shift, and reducing reliability.

In addition, oxide semiconductors such as indium oxide (InO) begin to dissolve at temperatures over 300° C., which can be easily reached during various processing steps for forming integrated circuits. The indium oxide can react with an adhesive layer (also known as glue layer) that is used to improve bonding between transistor layers, resulting in an interfacial layer having high S/D contact resistance (R_{csd}). Such thermal instability also increases with more oxygen defect generation, leading to performance decay and Iₒₙ drop.

In the present disclosure, multiple approaches are provided to improve the thermal stability of transistors. In a first approach, an interfacial layer between a source/drain electrode and a semiconductor layer is formed from a material having a higher bond dissociation energy than indium oxide. In a second approach, the interfacial layer between the source/drain electrode and a semiconductor layer is formed from a metal-doped oxide semiconductor material. In a third approach, a metal layer or a metal oxide layer is formed between the source/drain electrode and the interfacial layer.

These approaches increase the thermal stability and electrical conductivity of the transistor, and can improve functional interconnects in the transistor. This reduces reaction with the adhesive layer, improving the R_{csd} and improving mobility of the transistor. Improved resistance against chemical/physical damage may also be obtained.

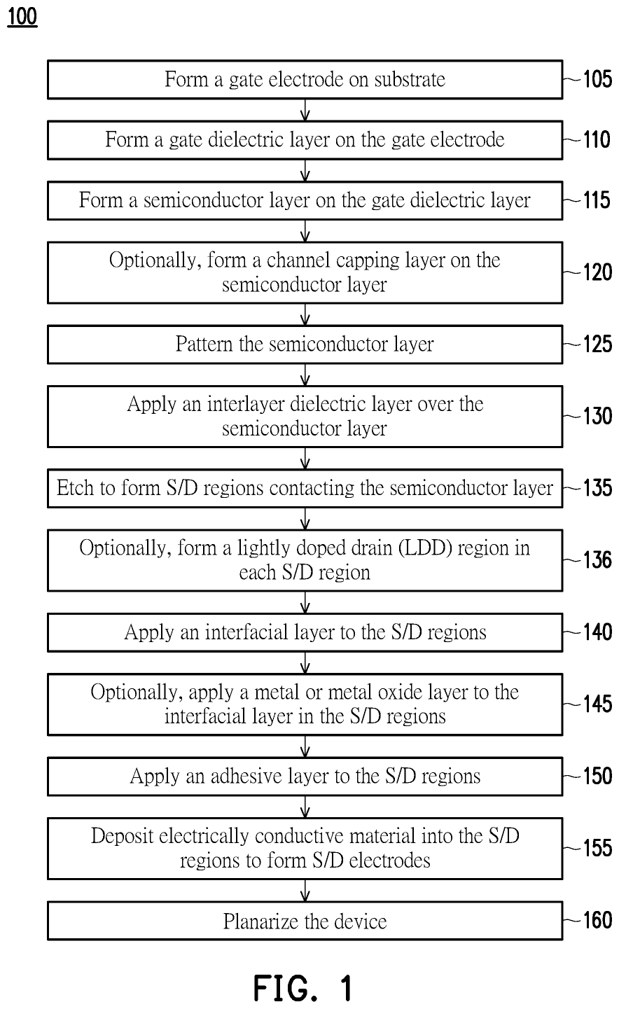

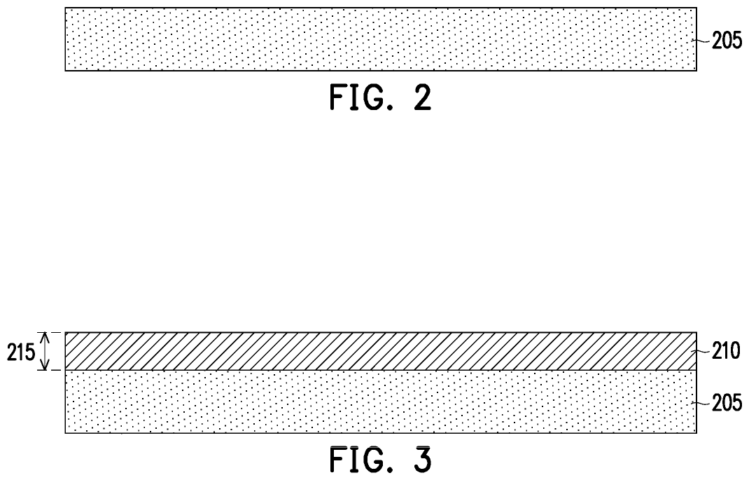

FIG. 1 is a flow chart illustrating a first method 100 for making a transistor, in accordance with some embodiments of the present disclosure. FIGS. 2-11 illustrate various steps of the first method, and these figures are discussed together. These figures are illustrated with reference to a bottom-gate transistor.

Referring first to FIG. 2, a substrate 205 is received or provided. This figure illustrates the beginning state of the substrate prior to making the transistor. The substrate is usually a wafer made of a semiconducting material. Such materials can include silicon, for example in the form of crystalline Si or polycrystalline Si. The substrate can also be made from other elementary semiconductors such as germanium or Al2O3 (sapphire), or may include a compound semiconductor such as silicon carbide (SiC), gallium nitride (GaN), gallium arsenide (GaAs), indium arsenide (InAs), and indium phosphide (InP). In particular embodiments, the wafer substrate is silicon.

Now, in step 105 of FIG. 1 and as illustrated in FIG. 3, a gate electrode 210 is formed. This may be done by forming an electrically insulating (or dielectric) layer, applying and patterning a photoresist layer to place the gate electrode in the desired location, etching the electrically insulating layer, depositing an electrically conductive material to form the gate electrode, and then removing the photoresist layer. It is noted that the electrically insulating layer is not shown in FIG. 3.

The electrically insulating layer is commonly formed using thermal oxidation of a silicon substrate. However, other processes may also be used, such as thermal oxidation, atomic layer deposition (ALD) or chemical vapor deposition (CVD), including plasma-enhanced atomic layer deposition (PEALD) or plasma-enhanced chemical vapor deposition (PECVD). The insulating layer may be formed from silicon dioxide (SiO₂), but can also be made of a high-k dielectric material (which has a dielectric constant greater than 3.9). Examples of suitable high-k dielectric materials include silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

The photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

The photoresist layer may then be baked or cured to remove the solvent and harden the photoresist layer. In some particular embodiments, the baking occurs at a temperature of about 90° C. to about 110° C. The baking can be performed using a hot plate or oven, or similar equipment.

The photoresist layer is then patterned via exposure to radiation. The radiation may be any light wavelength which carries a desired mask pattern, although ultraviolet (“UV”) radiation is typically used at the current time. UV radiation has a wavelength in the range of about 10 nanometers (“nm”) to about 400 nm, such as from KrF lasers (248 nm) or ArF lasers (193 nm). In particular embodiments, extreme ultraviolet (“EUV”) light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

The gate electrode, and any other electrically conductive components, can be formed by the deposition of any suitable electrically conductive material. Examples of such materials may include polycrystalline silicon (polysilicon); metals such as Al, Zr, W, Ru, Co, Ni, Pt, Au, Co, Rh, Pd, Bi, Ti, Ta, and the like; composites like TiN, WN, or TaN; or alloys thereof. The material may be deposited, for example, via evaporation or sputtering, plating, ALD, CVD, or other suitable methods. This may be followed by annealing, in which the metal reacts with the underlying exposed silicon. Chemical-mechanical planarization (CMP) or selective etching may be used to remove excess deposited material. The gate electrode may have a thickness 215 of about 10 nm to about 100 nm, although values outside of this range may also be acceptable.

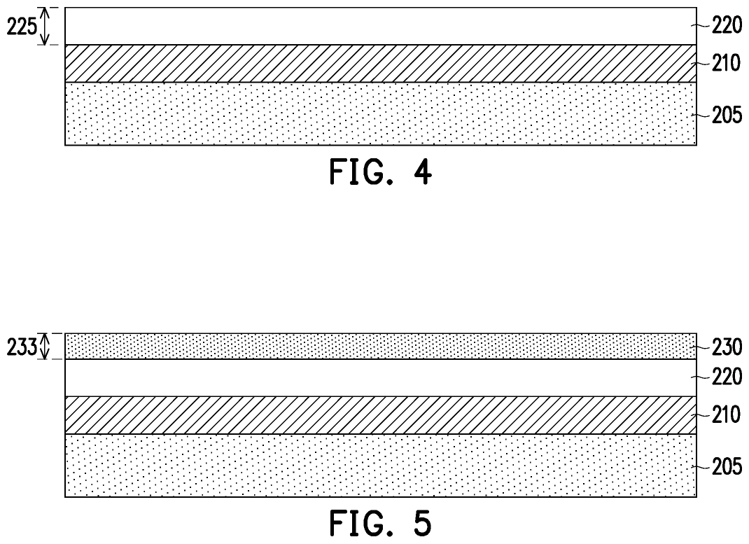

Next, in step 110 of FIG. 1 and as illustrated in FIG. 4, a gate dielectric layer 220 is formed upon the substrate, more specifically on the gate electrode 210. This may be formed in the same manner as described above. In particular embodiments, the gate dielectric layer 220 is formed from a high-k dielectric material. In some embodiments of the present disclosure, the high-k dielectric material has a dielectric constant higher than 5, or higher than 7, or higher than 10. Examples of high-k dielectric materials include those previously discussed. Other examples of suitable high-k dielectric materials can include Al₂O₃, HfO₂, HfLaO, and HfSiO. Other suitable dielectric materials may include ferroelectric materials (whose dielectric constant may change with temperature) and oxide-nitride-oxide (ONO) films. The gate dielectric layer may have a thickness 225 of about 1 nm to about 10 nm, although values outside of this range may also be acceptable.

Then, in step 115 of FIG. 1 and as illustrated in FIG. 5, a semiconductor layer 230 is formed upon the substrate, more specifically on the gate dielectric layer 220. The semiconductor layer can be formed using processes such as physical vapor deposition (PVD), chemical vapor deposition (CVD), or atomic layer deposition (ALD). In some specific embodiments, the semiconductor layer may have a thickness 233 of about 3 nm to about 20 nm, although values outside of this range may also be acceptable.

In particular embodiments, the semiconductor layer is formed from an oxide semiconductor. Oxide semiconductors typically provide high conductivity and high electron mobility, as well as a wide bandgap. N-type oxide semiconductors and p-type oxide semiconductors are known. Examples of oxide semiconductors may include zinc oxide (ZnO), magnesium oxide (MgO), gadolinium oxide (GdO), gallium oxide (Ga₂O₃), tin oxide (SnO₂), indium oxide (In₂O₃), indium tin oxide (ITO), cuprous oxide (Cu₂O), and binary, ternary, or quaternary combinations thereof. In more specific embodiments, the oxide semiconductor is InGaZnO (IGZO), which has the general formula InₓGa_{y}Zn_{z}O, where 0<x≤1; 0<y≤1; and 0<z≤1. The InGaZnO is optionally doped with a metal, having the formula InₓGa_{y}Zn_{z}O:M, where M is Ti, Al, Ag, W, Ce, Sn, V, or Sc.

Next, in step 120 of FIG. 1 and as illustrated in FIG. 6, a channel capping layer 240 is formed upon the substrate, more specifically upon the semiconductor layer 230. The capping layer can reduce exposure of the semiconductor layer to hydrogen atoms, which is known to damage oxide semiconductors. The channel capping layer can be formed by PVD, CVD, or ALD, or other suitable process. Suitable materials may include oxides such as silicon oxide; nitrides such as silicon nitride; or another dielectric material. It is noted that the presence of a channel capping layer is optional, and such layer does not need to be present to produce an operative transistor.

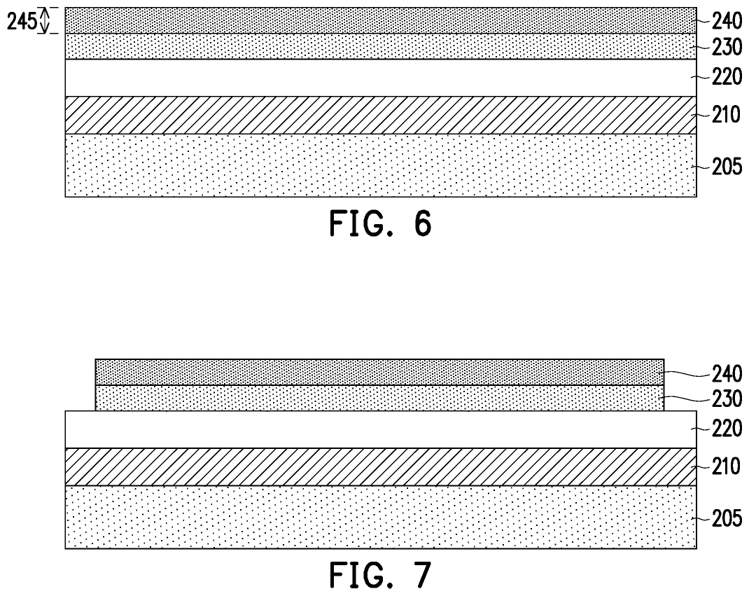

Then, in step 125 of FIG. 1 and as illustrated in FIG. 7, the semiconductor layer 230 is patterned. This may be done by applying and patterning a photoresist layer, etching to transfer the pattern to the semiconductor layer, and then removing the photoresist layer. As illustrated here, the channel capping layer 240 is also patterned.

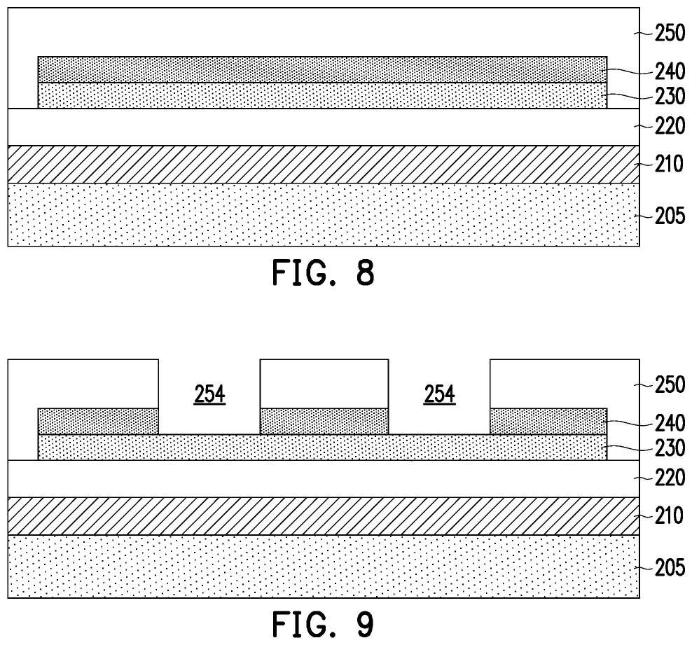

Continuing, in step 130 of FIG. 1 and as illustrated in FIG. 8, an interlayer dielectric (ILD) layer 250 is applied over the semiconductor layer 230. Suitable methods and materials for forming a dielectric layer have been previously described above in regard to step 105, and are applicable to this processing step as well. As illustrated here, the semiconductor layer 230 is encapsulated by the ILD layer 250.

Then, in step 135 of FIG. 1 and as illustrated in FIG. 9, etching is performed to form source/drain (S/D) regions 254 that contact the semiconductor layer 230. A photoresist layer is applied to the ILD layer and patterned, and different etch recipes are used to etch through each layer. As illustrated here, the S/D regions are the empty volume that extend through the ILD layer 250 and the channel capping layer 240.

Next, in optional step 136 of FIG. 1, a lightly-doped drain (LDD) region may be applied to the S/D regions 254. The LDD region will thus be located between the semiconductor layer 230 and the resulting source/drain electrodes. The LDD region reduces the hot carrier effect that can occur in the saturation region of the transistor. An LDD region is not illustrated in FIG. 8 or FIG. 9.

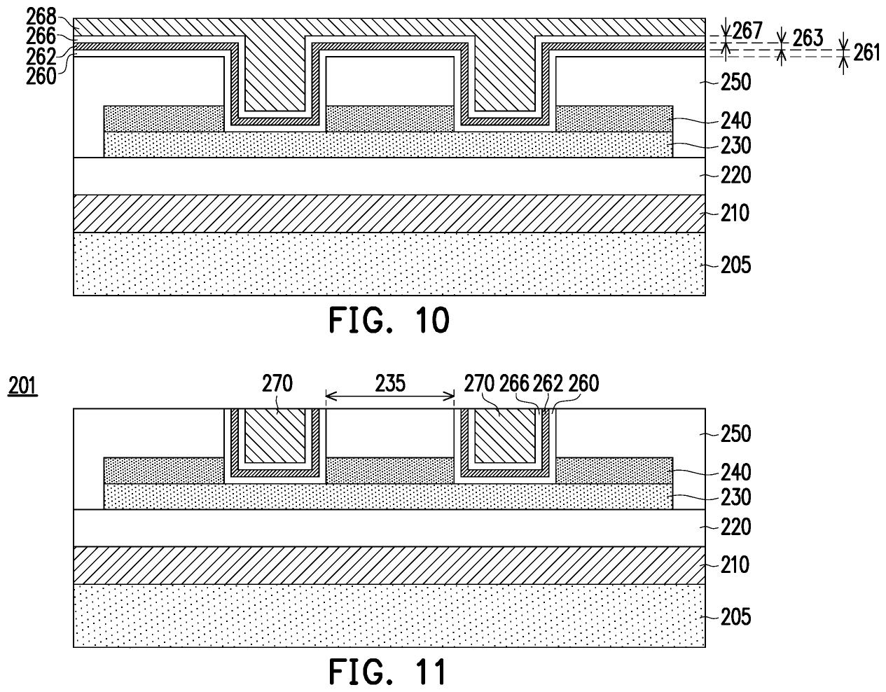

Next, in step 140 of FIG. 1 and as illustrated in FIG. 10, at least one interfacial layer 260 is applied to the S/D regions 254. As illustrated here, the interfacial layer also covers the ILD layer 250. In some particular embodiments, each interfacial layer has a thickness 261 of from about 0.5 nm to about 10 nm, although values outside of this range may also be acceptable. Desirably, the interfacial layer is more conductive than the semiconductor layer, to reduce the Schottky barrier height. The interfacial layer is a thin film and may be formed by ALD, PVD, CVD, or other suitable process such as ex situ film deposition.

Then, in optional step 145 of FIG. 1 and as illustrated in FIG. 10, a metal layer or metal oxide layer 262 is applied to the S/D regions 254. As illustrated here, the metal or metal oxide layer also covers the ILD layer 250. In some particular embodiments, when a metal is used, the layer 262 has a thickness 263 of from about 10 nm to about 100 nm, although values outside of this range may also be acceptable. In some particular embodiments, when a metal oxide is used, the layer 262 has a thickness 263 of from about 0.1 nm to about 20 nm, although values outside of this range may also be acceptable. The metal or metal oxide layer is a thin film and may be formed by ALD, PVD, CVD, or other suitable process such as ex situ film deposition.

In embodiments that correspond to the first approach, the interfacial layer is formed from a semiconducting material that has a higher bond dissociation energy (BDE) than indium oxide (In₂O₃). The BDE is the change in enthalpy that occurs when breaking a bond between two elements in a compound, and has units of kJ/mol. The BDE for a particular bond may change depending on the other elements present in the compound. For example, the BDE of the O—O bond in diatomic oxygen (O₂) is 497.4 kJ/mol, but the BDE of an O—O bond in ozone (O₃) is only ˜102 kJ/mol.

The BDEs of some bonds are provided in the following table, sorted in alphabetical order by the bond on the left-hand side and by BDE on the right-hand side:

| Bond | BDE (kJ/mol) | Bond | BDE (kJ/mol) |
|---|---|---|---|
| Cu—O | 287.4 | Zn—O | 250 |
| Ga—O | 374 | Cu—O | 287.4 |
| In—O | 346 | In—O | 346 |
| Ru—O | 528 | Ga—O | 374 |
| Sc—O | 671.4 | Sr—O | 426.3 |
| Sn—O | 528 | Ru—O | 528 |
| Sr—O | 426.3 | Sn—O | 528 |
| Ti—O | 668 | Ti—O | 668 |
| W—O | 720 | Sc—O | 671.4 |
| Zn—O | 250 | W—O | 720 |

For purposes of the present disclosure, the BDE of a particular multiple-element oxide semiconductor material is measured as the BDE of each bond that can be formed between oxygen and the other elements of the oxide semiconductor, weighted by their mole percentage in the interfacial layer. For example, the BDE of In₁Ga₁Zn₁O would be the weighted average of the BDEs of InO, GaO, and ZnO, or (316*0.33)+(374*0.33)+(250*0.33)=323.3 kJ/mol. But the BDE of In_{0.5}Ga₁Zn₁O would be [(316*0.2)+(374*0.4)+(250*0.4)=312.8 kJ/mol.

Some examples of materials that have a higher bond dissociation energy (BDE) than indium oxide (In₂O₃) include InₓSnₜO, Ga_{y}Zn_{z}O, InₓGa_{y}Zn_{z}O, InₓSnₜZn_{z}O, InₓSnₜTi_{w}O, or InₓSnₜGa_{y}Zn_{z}O, where 0<t≤1; 0<w≤1; 0<x≤1; 0<y≤1; and 0<z≤1.

In embodiments that correspond to the second approach, the interfacial layer is formed from a metal-doped oxide semiconductor material. In some embodiments, the oxide semiconductor material that is doped with the metal can include ZnO, In₂O₃, InₓSnₜO, Ga_{y}Zn_{z}O, InₓGa_{y}Zn_{z}O, InₓSnₜZn_{z}O, InₓSnₜTi_{w}O, or InₓSnₜGa_{y}Zn_{z}O, where 0<t≤1; 0<w≤1; 0<x≤1; 0<y≤1; and 0<z≤1. Some non-limiting examples of metal dopants that can be used with the oxide semiconductor material include TiO₂, WO₃, SnO₂, RuO₂, Sc_{q}O SrᵣCuₛO, SrᵣTi_{w}O, Mg, Ca, Ga, Hf, Al, Sn, V, Ti, Cd, or Cu, where 0<q≤1; 0<r≤1; and 0<s≤1 and w is as defined above. The amount of doping may be varied to obtain a desired balance between thermal reliability, carrier concentration, and desired state (amorphous/crystalline). In some embodiments, the doping may be performed so that the metal atom is present in the amount of about 0.1 to about 20 at % of the interfacial layer. The doping can be performed by ALD, CVD, PVD, or ion implantation. It is also noted that some metal-doped oxide semiconductor materials can also have a higher bond dissociation energy (BDE) than indium oxide (In₂O₃), or in other words may also be consistent with the first approach.

In embodiments that correspond to the third approach, the metal layer or metal oxide layer 262 is present, and will be formed between the source/drain electrode and the interfacial layer. Suitable metals may include Mg, Ca, Ga, Hf, Al, Sn, V, Ti, Cd, or Cu. Suitable metal oxides may include TiO₂, WO₃, SnO₂, RuO₂, Sc_{q}O SrᵣCuₛO, and SrᵣTi_{w}O, where q, r, s, and w are as defined above. In these embodiments, the interfacial layer may be made from ZnO, In₂O₃, InₓSnₜO, Ga_{y}Zn_{z}O, InₓGa_{y}Zn_{z}O, InₓSnₜZn_{z}O, InₓSnₜTi_{w}O, or InₓSnₜGa_{y}Zn_{z}O, where t, w, x, y, and z are as defined below.

Next, in step 150 of FIG. 1 and as illustrated in FIG. 10, an adhesive layer 266 is applied to the S/D regions 254. As illustrated here, the adhesive layer also covers the ILD layer 250. In some particular embodiments, the adhesive layer has a thickness 267 of from about 1 nm to about 50 nm, although values outside of this range may also be acceptable. Some examples of suitable materials for the adhesive layer include metal nitrides such as TaN, TiN, or WN; or Cu-, Al-, or Ti-containing alloys. The adhesive layer is a thin film and may be formed by ALD, PVD, CVD, or other suitable process such as ex situ film deposition.

Next, in step 155 of FIG. 1 and as illustrated in FIG. 10, an electrically conductive material 268 is deposited into the S/D regions, which will be used to form S/D electrodes. As illustrated here, the electrically conductive material also covers the ILD layer 250. The same methods and materials as described above for forming the gate electrode 210 are applicable to this processing step as well.

Continuing, in step 160 of FIG. 1 and as illustrated in FIG. 11, the device is planarized to separate and obtain the two S/D electrodes 270, so that they are only electrically connected through the semiconductor layer 230. The planarizing may be performed, for example, using a chemical mechanical polishing (CMP) process.

Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate, removing undesired materials and creating a highly level surface on the wafer. A post-CMP cleaning step is then carried out using rotating scrubber brushes along with a washing fluid to clean one or both sides of the wafer substrate.

FIG. 11 illustrates one example of the final bottom-gate transistor 201. The planarization has removed the various layers that were upon the ILD layer 250. The semiconductor channel length 235 between the S/D electrodes 270 may be from about 1 nanometer to about 100 nanometers.

More generally, the gate dielectric layer 220 separates the gate electrode 210 from the source and drain electrodes 270. The semiconductor layer 230 bridges the S/D electrodes, and is in contact with the gate dielectric layer 220. The semiconductor layer 230 can also be considered as separating the gate electrode 210 from the S/D electrodes 270. Put another way, the S/D electrodes and the gate electrode are on opposite sides of the semiconductor layer/gate dielectric layer.

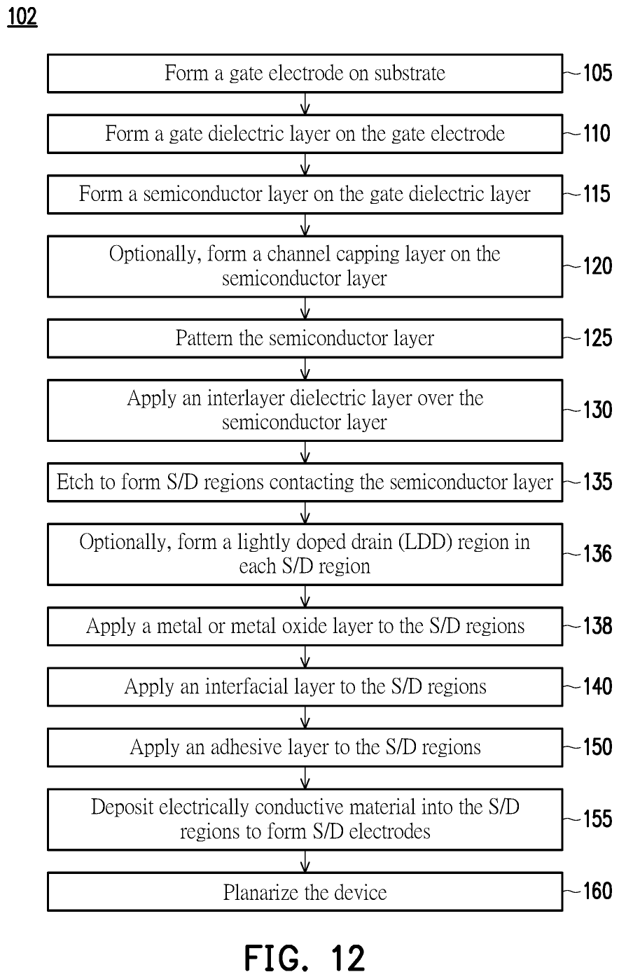

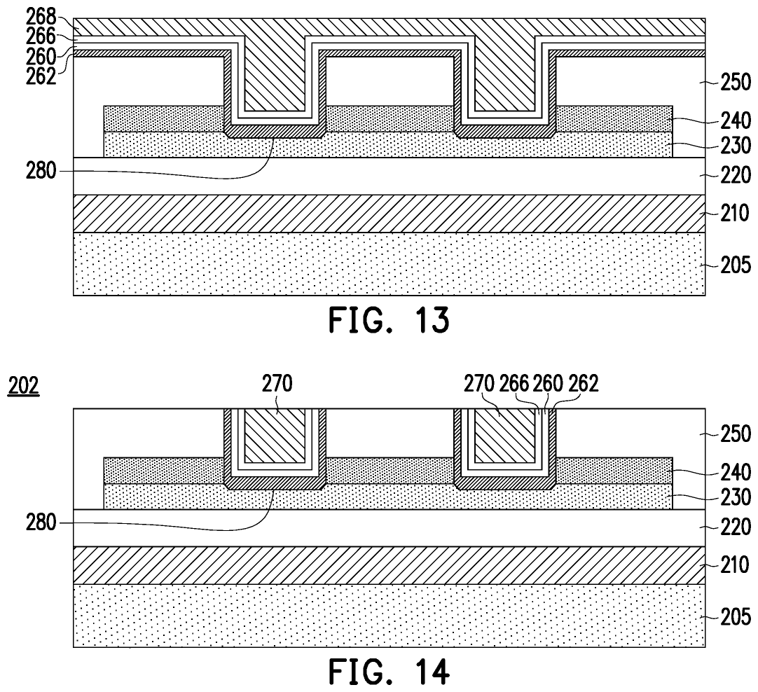

FIG. 12 is a flow chart illustrating a second method 102 for making a transistor, in accordance with some embodiments of the present disclosure. FIG. 13 and FIG. 14 illustrate particular steps of the second method, and these figures are discussed together. These figures are illustrated with reference to a bottom-gate transistor.

Steps 105-135 of the method of FIG. 12 are identical to those of the first method described in FIG. 1, and are illustrated in FIGS. 2-9. Continuing, then, in optional step 136 of FIG. 12 and as illustrated in FIG. 13, a lightly-doped drain (LDD) region 280 is applied to the S/D regions 254. The LDD region is thus located between the semiconductor layer 230 and the interfacial layer(s) 260.

Then, in step 138 of FIG. 12, a metal layer or metal oxide layer 262 is applied to the S/D regions 254. Next, in step 140, at least one interfacial layer 260 is applied to the S/D regions 254. Then, in step 150, an adhesive layer 266 is applied to the S/D regions 254. Next, in step 155, an electrically conductive material 268 is deposited into the S/D regions to form S/D electrodes 270. These steps are performed using the same methods and materials previously described. The resulting structure is illustrated in FIG. 13. Again, the layers 262, 260, 266 cover the ILD layer 250. Comparing the structure of FIG. 13 to the structure of FIG. 10, the main difference is that the locations of the interfacial layer 260 and the metal or metal oxide layer 262 have been reversed. In addition, the LDD region 280 is illustrated.

Continuing, in step 160 of FIG. 12, the device is planarized to obtain separate the two S/D electrodes 270. This step is performed using the same methods and materials previously described. FIG. 14 illustrates the resulting structure, which is another example of a bottom-gate transistor 202.

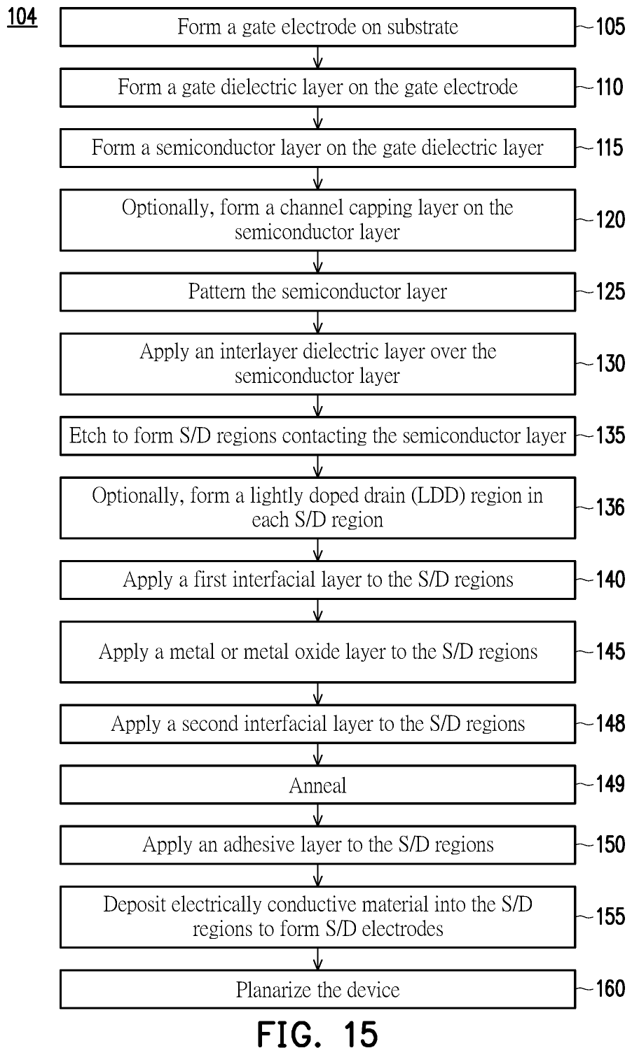

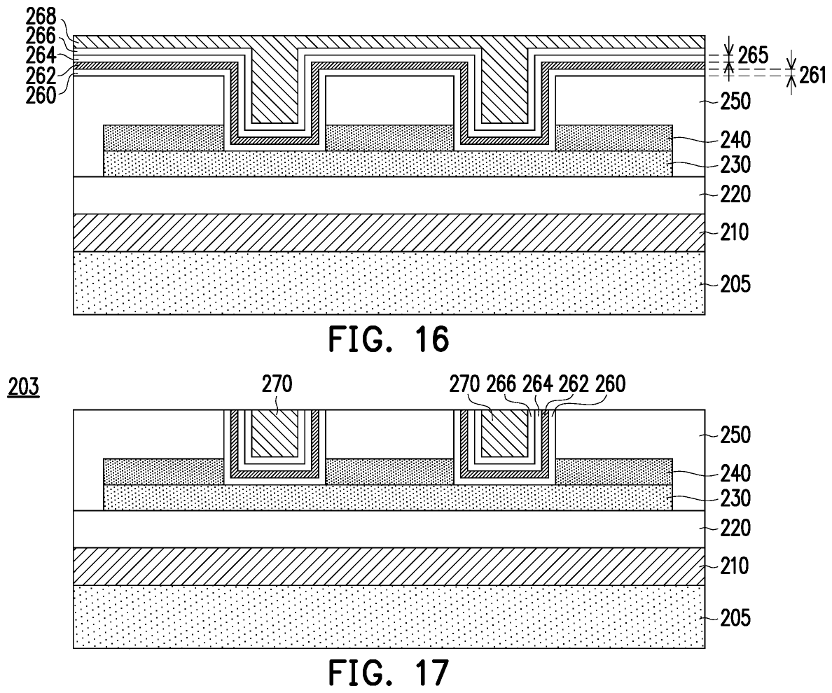

FIG. 15 is a flow chart illustrating a third method 104 for making a transistor, in accordance with some embodiments of the present disclosure. FIG. 16 and FIG. 17 illustrate particular steps of the third method, and these figures are discussed together. These figures are illustrated with reference to a bottom-gate transistor.

Steps 105-135 of the method of FIG. 15 are identical to those of the first method described in FIG. 1, and are illustrated in FIGS. 2-9. Continuing, then, in optional step 136 of FIG. 15, a lightly-doped drain (LDD) region 280 is applied to the S/D regions 254. The LDD region is not illustrated here.

Next, in step 140 and referring to FIG. 16, a first interfacial layer 260 is applied to the S/D regions 254. Then, in step 145, a metal layer or metal oxide layer 262 is applied to the S/D regions 254. Next, in step 148, a second interfacial layer 264 is applied to the S/D regions 254. The second interfacial layer has a thickness 265. The thickness of the first interfacial layer and the second interfacial layer may independently be from about 0.25 nm to about 10 nm, although values outside of this range may also be acceptable. It is contemplated that the two interfacial layers 260, 264 will be made of the same material. These steps are performed using the same methods and materials previously described.

Next, in step 150 of FIG. 15, an adhesive layer 266 is applied to the S/D regions 254. Then, in step 155, an electrically conductive material 268 is deposited into the S/D regions to form S/D electrodes 270. These steps are performed using the same methods and materials previously described. The resulting structure is illustrated in FIG. 16. Again, the layers 262, 260, 264, 266 cover the ILD layer 250. Comparing the structure of FIG. 16 to the structures of FIG. 10 and FIG. 13, the main difference is that the metal or metal oxide layer 262 is located between two interfacial layers and there are a total of three layers, rather than only two layers with the metal or metal oxide layer to one side of the interfacial layers.

Continuing, in step 160 of FIG. 15, the device is planarized to obtain separate the two S/D electrodes 270. FIG. 17 illustrates another example of the final bottom-gate transistor 203.

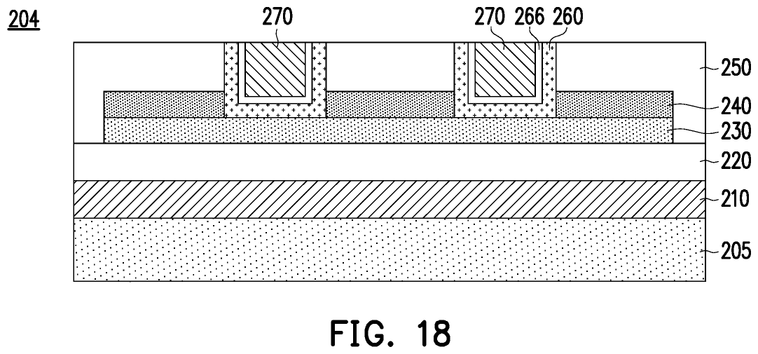

Referring now to the structures of FIG. 11, FIG. 14, and FIG. 17, these structures contain a distinct interfacial layer 260, 264 and a distinct metal or metal oxide layer 262 in various orders. In some further embodiments, it is contemplated that the metal or metal oxide layer 262 is used as the dopant for the oxide semiconductor material in the interfacial layer(s) 260, 264, to obtain a metal-doped oxide semiconductor material. For example, the transistor can be annealed to promote diffusion of the metal or metal oxide from layer 262 into the layers 260, 264, as indicated by step 149 in FIG. 15. This annealing may be performed at any time after the layers 260, 262, 264 are deposited. The resulting transistor 204 is illustrated in FIG. 18, where the interfacial layer 260 is a metal-doped oxide semiconductor material. The metal or metal oxide layer 262 is no longer distinguishable from the interfacial layer. Thus, the structures of FIG. 11, FIG. 14, and FIG. 17 might also be considered intermediates.

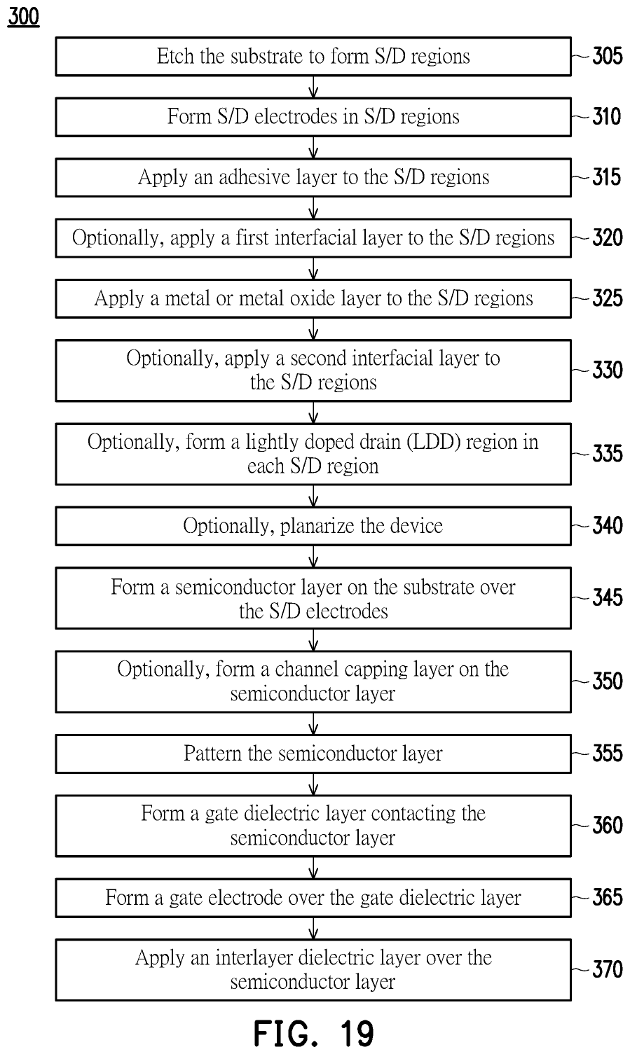

FIG. 19 is a flow chart illustrating a fourth method 300 for making a transistor, in accordance with some embodiments of the present disclosure. FIGS. 20-29 illustrate particular steps of the fourth method, and these figures are discussed together. These figures are illustrated with reference to a top-gate transistor.

FIG. 20 again illustrates the beginning state of the substrate 205 prior to making the transistor.

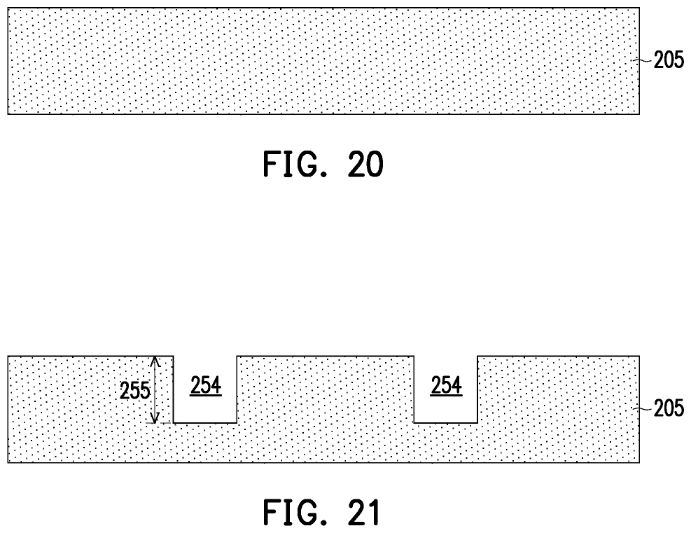

Next, in step 305 of FIG. 19 and as illustrated in FIG. 21, the substrate is etched to form S/D regions 254. The S/D region is etched to a depth 255 which is sufficient to support the layers that may be applied therein.

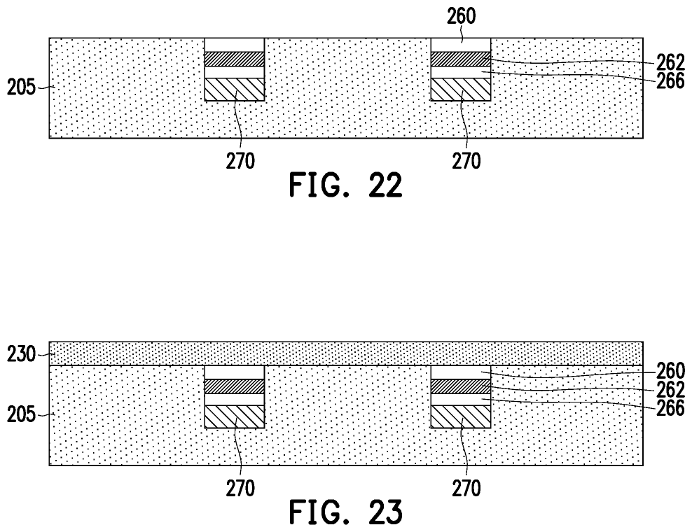

Continuing, in step 310 of FIG. 19 and as illustrated in FIG. 22, material is deposited into the S/D regions to form S/D electrodes 270. Electrically conductive materials may be deposited using the methods and materials previously described. Alternatively, ion implantation may be used to form the S/D electrodes in the portion of the wafer substrate located below the S/D regions. Briefly, an ion implanter is used to implant atoms into a silicon crystal lattice, modifying the conductivity of the lattice in the implanted location. An ion implanter generally includes an ion source, a beam line, and a process chamber. The ion source produces the desired ions (here, for example, Co, Ti, Ni, Pt, or Pb, depending on desired N- or P-type electrode). The beam line organizes the ions into a beam having high purity in terms of ion mass, energy, and species. The ion beam is then used to irradiate the wafer substrate in a process chamber. The ion beam strikes the exposed regions on the wafer substrate, and the ions can be implanted into the substrate as dopants at desired depths.

Next, in step 315 of FIG. 19 and referring still to FIG. 22, an adhesive layer 266 is applied to the S/D regions, over the S/D electrodes 270. Continuing, in optional step 320, a first interfacial layer 260 to the S/D regions, and more specifically over the adhesive layer 266. Then, in step 325, a metal or metal oxide layer 262 is applied to the S/D regions. Next, in optional step 330, a second interfacial layer 264 is applied to the S/D regions. At least one interfacial layer is applied. Then, in optional step 335 of FIG. 1, a lightly-doped drain (LDD) region may be applied to the S/D regions 254. These layers form thin films and fill up the S/D regions 254. The device may be planarized to remove any material upon the substrate, if desired, as indicated in optional step 340.

Depending on which of these steps is implemented, the resulting structure will have the metal or metal oxide layer 262 and either one or two interfacial layers 260, 264, with the interfacial layer potentially being on either side of the metal or metal oxide layer 262. In FIG. 22, interfacial layer 264 is present upon metal or metal oxide layer 262, or put another way the metal or metal oxide layer is between the S/D electrodes and the interfacial layer. The LDD region is not illustrated here.

Next, in step 345 of FIG. 19 and as illustrated in FIG. 23, the semiconductor layer 230 is formed upon the substrate 205, specifically over the S/D electrodes 270. It is noted that the S/D electrodes should be entirely covered by the semiconductor layer, as exposure to oxygen may cause adhesion problems with the S/D electrodes due to oxidation, especially when the S/D electrodes are made of a metal.

If desired, in optional step 350 of FIG. 19, a channel capping layer can be formed over the semiconductor layer 230. The channel capping layer is not illustrated.

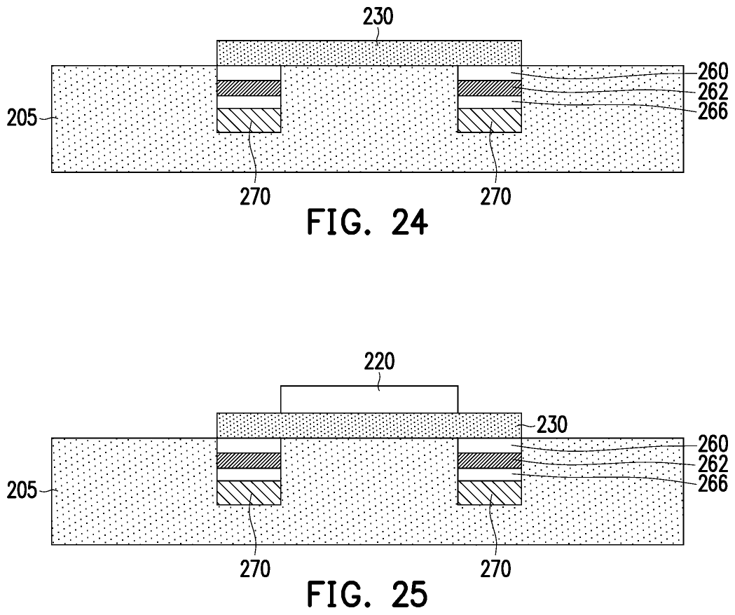

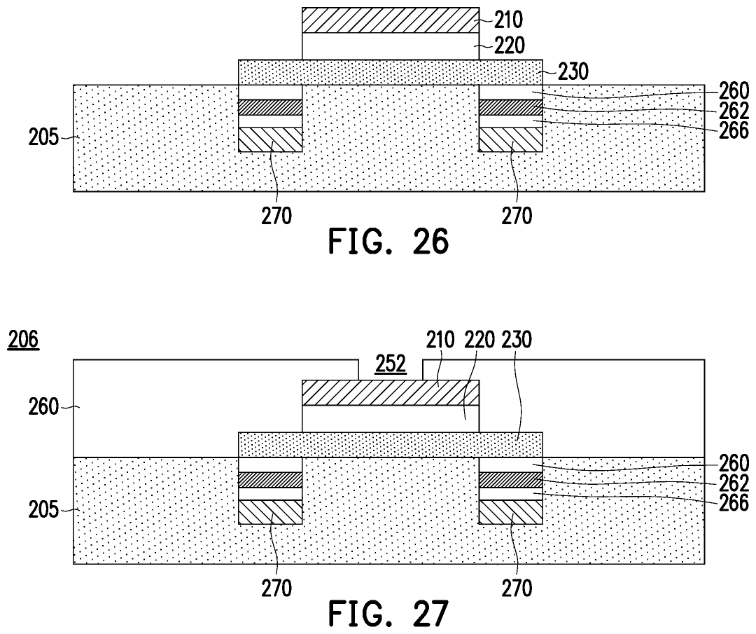

Next, in step 355 of FIG. 19 and as illustrated in FIG. 24, the semiconductor layer 230 is patterned. The semiconductor layer 230 is patterned so as to contact both S/D electrodes 270. Continuing, in step 360 of FIG. 12 and as illustrated in FIG. 25, a gate dielectric layer 220 is formed that contacts the semiconductor layer 230. Then, in step 365 of FIG. 19 and as illustrated in FIG. 26, a gate electrode 210 is formed over the gate dielectric layer 220. Finally, in step 370 of FIG. 19 and as illustrated in FIG. 27, an interlayer dielectric layer 250 is formed over the semiconductor layer 230. As illustrated here, the ILD layer 250 is also etched to form a gap 252 that allows electrical contact with the gate electrode 210.

FIG. 27 also illustrates one embodiment of a final top-gate transistor 206. It is noted the semiconductor layer 230 does not need to fully cover the source/drain electrodes 270.

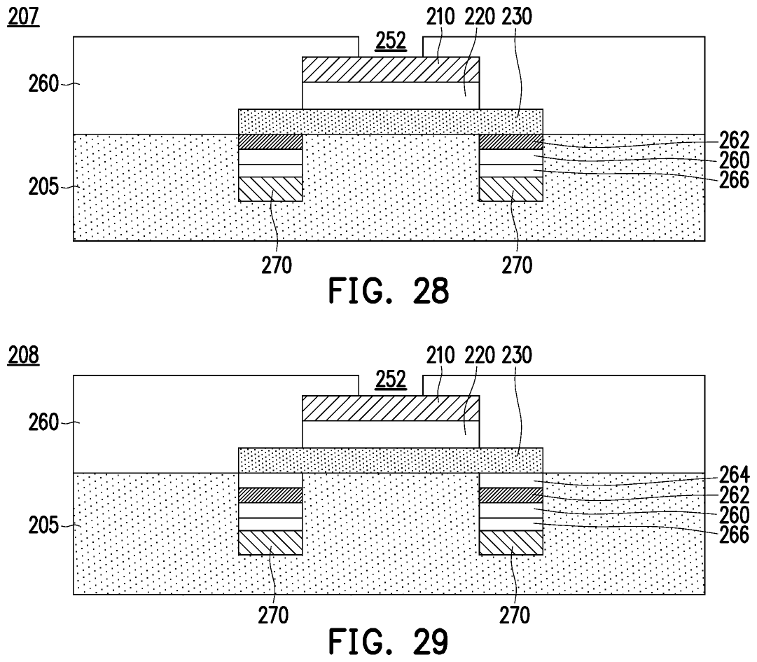

FIG. 28 illustrates a second embodiment of a final top-gate transistor 207. Here, interfacial layer 260 is below the metal or metal oxide layer 262, or put another way the interfacial layer is between the S/D electrodes and the metal or metal oxide layer.

FIG. 29 illustrates a third embodiment of a final top-gate transistor 208. Here, the metal or metal oxide layer 262 is located between two interfacial layers 260, 264.

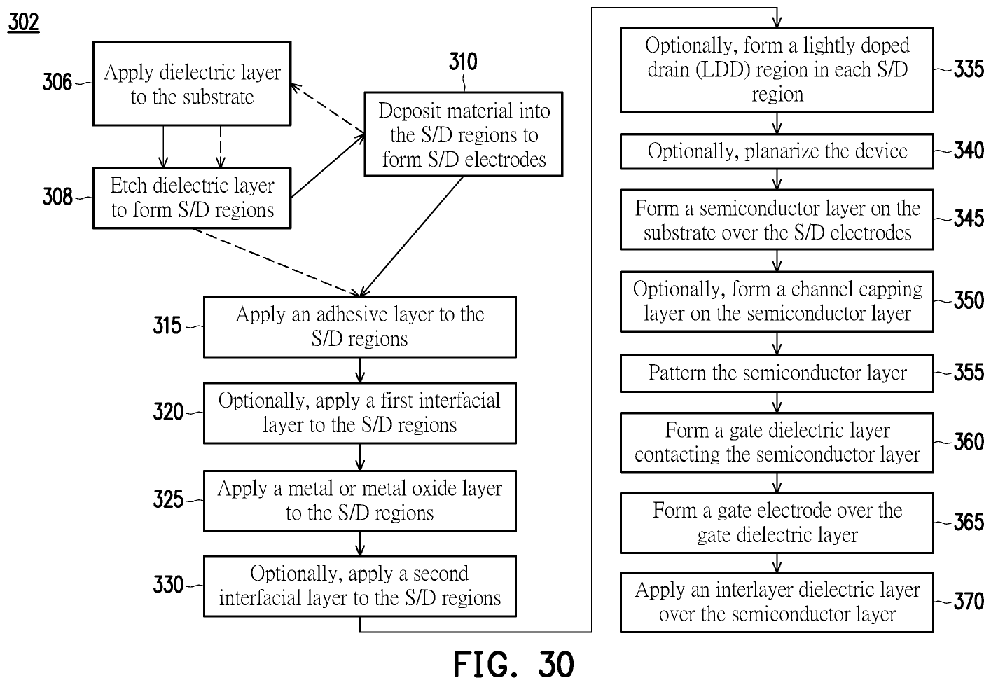

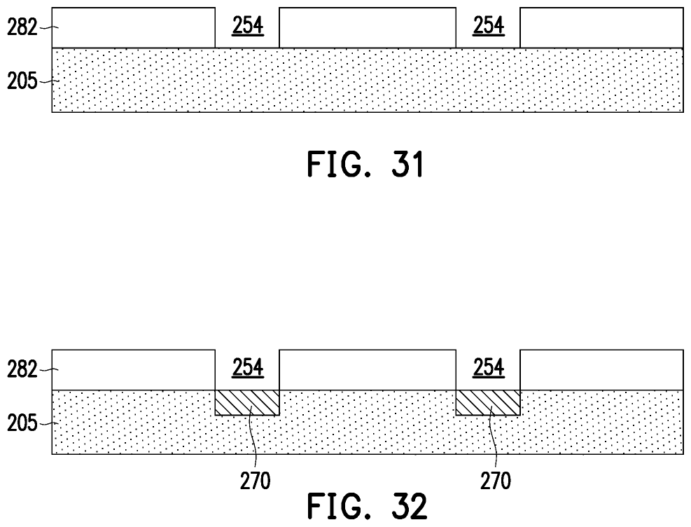

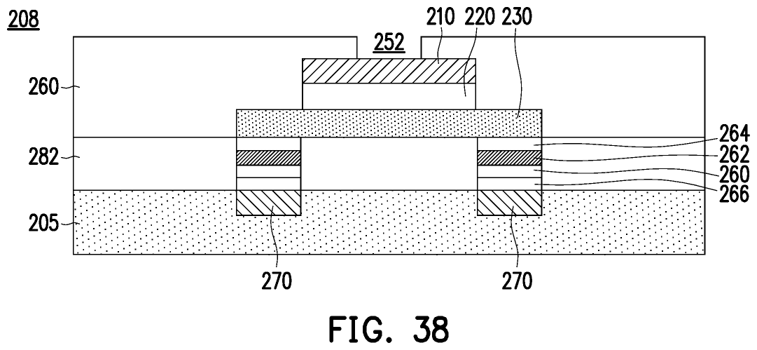

FIG. 30 is a flow chart illustrating a fifth method 302 for making a transistor, in accordance with some embodiments of the present disclosure. FIGS. 31-38 illustrate particular steps of the fifth method, and these figures are discussed together. These figures are illustrated with reference to a top-gate transistor.

The fifth method of FIG. 30 differs from the fourth method of FIG. 19 by forming a dielectric layer upon the substrate before making the transistor. The order of the first few steps may be performed in different sequences, as indicated by the solid lines and dashed lines in FIG. 30.

The first sequence follows the solid lines. Initially, in step 306 of FIG. 30, a dielectric layer is formed upon the substrate. This may be done by thermal oxidation of a silicon substrate to form a silicon dioxide dielectric layer, or by other suitable processes such as ALD, PVD, or CVD. Then, in step 308 of FIG. 30, the dielectric layer is etched to form S/D regions 254. The resulting structure is shown in FIG. 31. Next, in step 310, material is deposited into the S/D regions to form S/D electrodes 270. Electrically conductive materials may be deposited or ion implantation may be used to form the S/D electrodes in the portion of the wafer substrate located below the S/D regions, as previously described. Etching may be performed to remove excess material if desired. The resulting structure is shown in FIG. 32.

The fifth method of FIG. 30 differs from the fourth method of FIG. 19 by forming a dielectric layer upon the substrate before making the transistor. The order of the first few steps may be performed in different sequences, as indicated by the solid lines and dashed lines in FIG. 30.

The first sequence follows the solid lines. Initially, in step 306 of FIG. 30, a dielectric layer is formed upon the substrate. This may be done by thermal oxidation of a silicon substrate to form a silicon dioxide dielectric layer, or by other suitable processes such as ALD, PVD, or CVD. Then, in step 308 of FIG. 30, the dielectric layer is etched to form S/D regions 254. The resulting structure is shown in FIG. 31. Next, in step 310, material is deposited into the S/D regions to form S/D electrodes 270. Electrically conductive materials may be deposited or ion implantation may be used to form the S/D electrodes in the portion of the wafer substrate located below the S/D regions, as previously described. Etching may be performed to remove excess material if desired. The resulting structure is shown in FIG. 32.

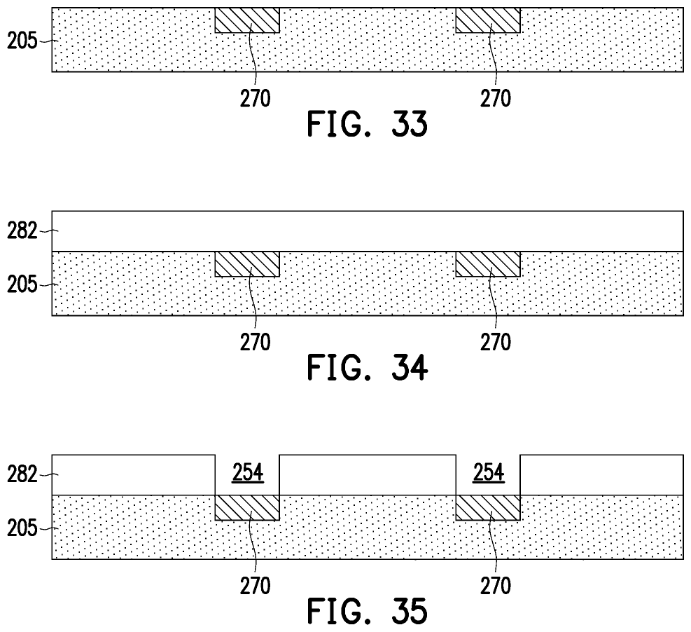

The second sequence follows the dashed lines. In this sequence, S/D electrodes 270 are first formed in step 310. This may be done by ion implantation, or by metal deposition, annealing, and removal of excess material. The resulting structure is shown in FIG. 33. Next, in step 306 of FIG. 30, the dielectric layer 282 is formed upon the substrate 205. The resulting structure is shown in FIG. 34. Then, in step 308,, the dielectric layer is etched to form S/D regions 254. The resulting structure is shown in FIG. 35 (which is identical to FIG. 32).

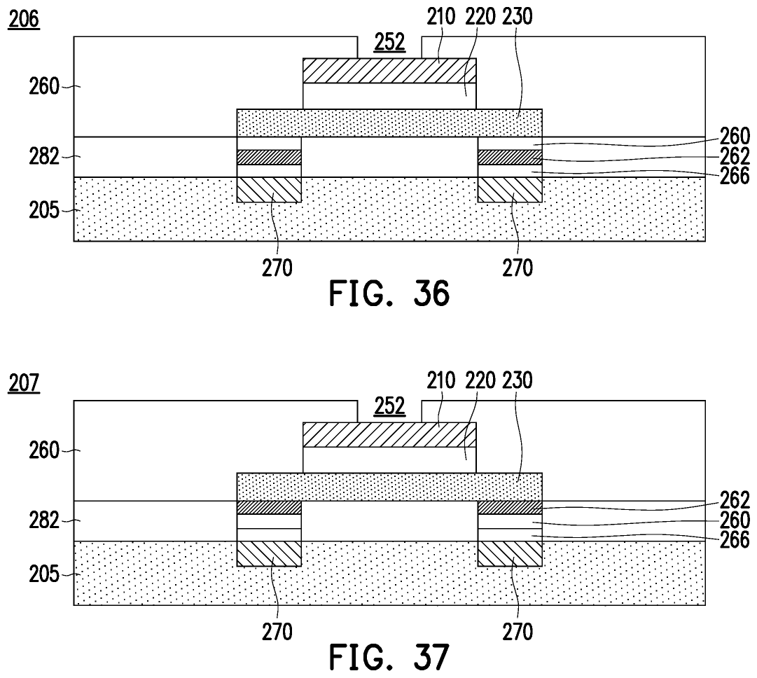

The remaining process steps 315-370 are identical to those described in FIG. 19. FIGS. 36-38 illustrate three different embodiments of top-gate transistors 206, 207, 208. The main difference between these transistors and the transistors of FIGS. 27-29 is that the interfacial layers 260, 264 and the metal or metal oxide layer 262 are located in a dielectric layer 282 instead of the substrate 205.

It is noted that in some applications, the gate electrode 210 is referred to as the write line, one S/D electrode 270 is referred to as the source line, and the other S/D electrode 270 is referred to as the bit line. These terms can be interchanged, and should be considered as also being used in the discussion of transistors herein. It is also noted that while FIGS. 1-38 describe forming a single transistor on a wafer substrate, during chip production large numbers of transistors are formed concurrently on the wafer substrate. The present disclosure should be construed accordingly.

The resulting transistor can be used in several different applications and systems. The transistor can be used in charge coupled devices (CCDs), complementary metal-oxide semiconductor (CMOS) image sensors, contact image sensors (CIS), and ambient light sensors (ALS). Such sensors can be used in systems such as mobile telephones, facial recognition systems, or as motion sensors for automotive applications, security applications, energy efficiency, etc. Random access memory uses a transistor to read and write bit values to a memory cell (nonvolatile or volatile). The transistor may be integrated with a Micro-Electro-Mechanical Systems (MEMS) device on a single chip. The MEMS device may include a plurality of elements formed from metal, polysilicon, dielectric, and/or other materials. The MEMS device may include mechanical structures, electrical structures, or fluid structures.

The addition of various interfacial/metal/metal oxide layers between the S/D electrodes and the semiconductor layer provide multiple advantages. These layers have improved thermal stability while maintaining high conductivity. They improve the functional interconnects between the various components of the transistor. They reduce the Schottky barrier height. They reduce the contact resistance between the S/D electrodes (R_{csd}), and will not begin decomposition even after exposure to temperatures up to 400° C. This can keep the R_{csd} below 200 ohms, and also permits more flexibility in back-end processes (although exposure to temperatures below 300° C. is still preferred). They can increase the on-current (Iₒₙ), improving mobility. They can also create further protection against chemical or physical damage. Finally, the use of these layers also reduces the number of oxygen vacancy states and photogenerated holes that may arise in the semiconductor layer. This in turn reduces any changes in charge carrier concentration which might otherwise occur across the semiconductor layer. Charge carrier concentration is a key factor in maintaining high carrier mobility and high driving speed, which improves the reliability of the overall semiconductor device.

The improvements in thermal stability due to use of various materials in the interfacial layer and the metal or metal oxide layer are illustrated here using two-dimensional field effect transistors (FET). However, these disclosures may also be applied for use in three-dimensional transistors such as FinFETs and Gate-All-Around transistors.

Various embodiments of the present disclosure thus relate to transistors comprising at least one source/drain electrode; an adhesive layer contacting the at least one source/drain electrode; a semiconductor layer; and at least one interfacial layer located between the adhesive layer and the semiconductor layer. The at least one interfacial layer comprises a material having a higher bond dissociation energy than indium oxide.

Other embodiments of the present disclosure relate to transistors comprising at least one source/drain electrode; an adhesive layer contacting the at least one source/drain electrode; a semiconductor layer; and at least one interfacial layer located between the adhesive layer and the semiconductor layer. The at least one interfacial layer comprises a metal-doped oxide semiconductor material.

Still other embodiments of the present disclosure relate to transistors comprising at least one source/drain electrode; an adhesive layer contacting the at least one source/drain electrode; and a semiconductor layer. At least one interfacial layer and at least one metal or metal oxide layer are located between the adhesive layer and the semiconductor layer.

Also disclosed herein are methods for making a transistor. A semiconductor layer is formed on a substrate. Etching is performed to form at least one S/D region that contacts the semiconductor layer. At least one interfacial layer is applied to the at least one S/D region. An adhesive layer is applied to the at least one S/D region. An electrically conductive material is deposited into the at least one S/D region to form an S/D electrode. In some instances, the at least one interfacial layer comprises a material having a higher bond dissociation energy than indium oxide. In other instances, the at least one interfacial layer comprises a metal-doped oxide semiconductor material. In yet other instances, a metal or metal oxide layer is also present, adjacent to the interfacial layer. In some further embodiments, the substrate is annealed so that the metal layer or metal oxide layer dopes the semiconductor layer.

The order of these steps may vary, for example depending on whether a bottom-gate transistor or a top-gate transistor is made.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
at least one source/drain electrode;
an adhesive layer contacting the at least one source/drain electrode;
a semiconductor layer; and
at least one interfacial layer located between the adhesive layer and the semiconductor layer;
wherein the at least one interfacial layer comprises a material having a higher bond dissociation energy than indium oxide.

2. The transistor of claim 1, wherein the at least one interfacial layer comprises a metal-doped oxide semiconductor material.

3. The transistor of claim 2, wherein the oxide semiconductor material comprises ZnO, In₂O₃, InₓSnₜO, Ga_{y}Zn_{z}O, InₓGa_{y}Zn_{z}O, InₓSnₜZn_{z}O, InₓSnₜTi_{w}O, or InₓSnₜGa_{y}Zn_{z}O, where 0<t≤1; 0<w≤1; 0<x≤1; 0<y≤1; and 0<z≤1.

4. The transistor of claim 2, wherein the oxide semiconductor material is doped with TiO₂, WO₃, SnO₂, RuO₂, Sc_{q}O SrᵣCuₛO, SrᵣTi_{w}O, Mg, Ca, Ga, Hf, Al, Sn, V, Ti, Cd, or Cu, where 0<q≤1; 0<r≤1; 0<s≤1; and 0<w≤1.

5. The transistor of claim 2, wherein the metal comprises from about 0.1 to about 20 at % of the metal-doped oxide semiconductor material.

6. The transistor of claim 1, further comprising a metal layer or a metal oxide layer located between the adhesive layer and the semiconductor layer.

7. The transistor of claim 6, wherein the metal oxide layer has a thickness of about 0.1 nm to about 20 nm.

8. The transistor of claim 6, having a total of two interfacial layers, wherein the metal layer or metal oxide layer is located between the two interfacial layers.

9. The transistor of claim 6, wherein the metal oxide layer comprises TiO₂, WO₃, SnO₂, RuO₂, Sc_{q}O SrᵣCuₛO, or SrᵣTi_{w}O, where 0<q≤1; 0<r≤1; 0<s≤1; and 0<w≤1.

10. The transistor of claim 6, wherein the metal layer has a thickness of about 10 nm to about 100 nm.

11. The transistor of claim 6, wherein the metal layer comprises Mg, Ca, Ga, Hf, Al, Sn, V, Ti, Cd, or Cu.

12. The transistor of claim 1, wherein the at least one interfacial layer comprises InₓSnₜO, Ga_{y}Zn_{z}O, InₓGa_{y}Zn_{z}O, InₓSnₜZn_{z}O, InₓSnₜTi_{w}O, or InₓSnₜGa_{y}Zn_{z}O, where 0<t≤1; 0<w≤1; 0<x≤1; 0<y≤1; and 0<z≤1.

13. The transistor of claim 1, further comprising a lightly doped drain (LDD) region between the at least one interfacial layer and the semiconductor layer.

14. The transistor of claim 1, wherein the at least one interfacial layer has a thickness of about 0.5 nm to about 10 nm.

15. A transistor, comprising:
at least one source/drain electrode;
an adhesive layer contacting the at least one source/drain electrode;
a semiconductor layer; and
at least one interfacial layer located between the adhesive layer and the semiconductor layer;
wherein the at least one interfacial layer comprises a metal-doped oxide semiconductor material.

16. The transistor of claim 15, wherein the metal-doped oxide semiconductor material has a higher bond dissociation energy than indium oxide.

17. The transistor of claim 15, further comprising a metal layer or a metal oxide layer located between the adhesive layer and the semiconductor layer.

18. A transistor, comprising:
at least one source/drain electrode;
an adhesive layer contacting the at least one source/drain electrode;
a semiconductor layer;
at least one interfacial layer located between the adhesive layer and the semiconductor layer; and
at least one metal or metal oxide layer located between the adhesive layer and the semiconductor layer.

19. The transistor of claim 18, having a total of two interfacial layers, wherein the at least one metal or metal oxide layer is located between the two interfacial layers.

20. The transistor of claim 18, wherein the at least one interfacial layer directly contacts the at least one metal or metal oxide layer.
